(19) United States
(12) Patent Application Publication
(10) Pub. No.: US 2026/0230298 A1
(43) Pub. Date: Aug. 6, 2026

(54) DIRECT-CURRENT (DC) RESTORATION WITH CLOCK-TO-DATA SYNCHRONIZATION IN ALTERNATING-CURRENT (AC)-COUPLED LINK

(71) Applicant: NVIDIA Corporation, Santa Clara, CA (US)

(72) Inventors: Ofek Abadi, Nahariya (IL); Omer Wolkovitz, Kfar Saba (IL)

(21) Appl. No.: 19/047,178

(22) Filed: Feb. 6, 2025

(51) Int. Cl. H04L 7/00; H03M 1/00

(52) U.S. Cl. CPC H04L 7/0079; H03M 1/001

(57) ABSTRACT

A circuit includes clock detection circuitry to detect, at transitions of a clock signal transmitted across an alternating current (AC)-coupled unidirectional link, a first maximum value and a first minimum value of common mode-based amplitudes of the clock signal. A data receiver (RX) circuit is coupled to the clock detection circuitry and configured to receive a data signal from a data channel of the link. The RX circuit imposes a second maximum value and a second minimum value on bit transitions of the data signal based on, respectively, the first maximum value and the first minimum value obtained from the clock signal. The RX circuit also samples the data signal using the clock signal.

### TECHNICAL FIELD

At least one embodiment generally pertains to communications systems, and more specifically, but not exclusively, to direct-current (DC) restoration with clock-to-data synchronization in an alternating current (AC)-coupled link.

### BACKGROUND

In single-ended, AC-coupled unidirectional links, a transmitter (TX) of a communication system can drive a channel through a serial capacitor. Therefore, the voltage levels in the receiving side of the link can be generated by a DC restoration mechanism. In such links, the clock can be forwarded from a TX side to a receiving (RX) side. Since a clock and random data can experience different inter-symbol interference (ISI), the amplitude of the data and clock signals can be different when arriving at RX input pads of an RX circuit. The difference in amplitude, however, can be translated to different delays of the clock and the data signals and can cause sampling, by the clock, at the wrong point of the data signal. This incorrect sampling timing can cause incorrect sampling of a received data stream.

### BRIEF DESCRIPTION OF DRAWINGS

Various embodiments in accordance with the present disclosure will be described with reference to the drawings, in which:

FIG. 1A is a schematic block diagram of an example system composed of an AC-coupled unidirectional link employing circuitry for synchronizing amplitudes of data and clock signals for purposes of DC restoration before data sampling according to various embodiments;

FIG. 1B is a diagram of a clock signal having the maximum value and minimum value of common mode-based amplitudes detected for use in forcing the amplitudes of the data signal according to some embodiments;

FIG. 1C is a diagram of an incoming data signal, at an input terminal of a data RX circuit, having imposed a maximum value and a minimum value of amplitudes according to some embodiments;

FIG. 2 is a flow chart of a method of operating a circuit for synchronizing maximum and minimum values of common mode-based amplitudes between the clock and data signals when performing DC restoration before data sampling according to various embodiments;

FIG. 3A is a schematic block diagram of an example system composed of an AC-coupled unidirectional link employing circuitry for synchronizing amplitudes of a data signal and a differential clock signal for purposes of DC restoration before data sampling according to alternative embodiments;

FIG. 3B is a diagram of a clock signal having the maximum value and minimum value of common mode-based amplitudes detected for use in forcing the amplitudes of the data signal according to some embodiments;

FIG. 4 is a schematic diagram of an example differential peak-to-peak detector that can be employed in the example system of FIG. 3A according to at least one embodiment;

FIG. 5A illustrates an example communication system in which the AC-coupled unidirectional (or short-reach) link operates according to at least one embodiment;

FIG. 5B illustrates a block diagram of an example communication system in which the AC-coupled unidirectional (or short-reach) link operates according to at least one embodiment;

FIG. 6 illustrates an example computer system including a spectrum hardware engine and an error correction block according to at least one embodiment;

FIG. 7 is a block diagram of a computing system having two processing devices coupled to each other and multiple networks according to at least one embodiment;

FIG. 8 is a block diagram of a computing system having a central processing unit (CPU) and a graphics processing unit (GPU) in a single integrated circuit according to at least one embodiment; and

FIG. 9 is a block diagram of a computing system having tensor core graphics processing units (GPUs) according to at least one embodiment.

### DETAILED DESCRIPTION

In some implementations of the circuits, devices, systems, and methods described herein are clock-to-data amplitude-synchronization techniques of DC restoration before sampling data received over an AC-coupled link. These implementations focus particularly on imposing maximum and minimum values of common mode-based amplitudes, which are detected in a clock signal received over the link, in the data signal before the data signal is sampled.

The ever-increasing demand for high-performance computing requires high-density, low-power interconnects to move large amounts of data between co-packaged dies. There are some architectures designed to meet those criteria like simultaneous bi-directional (SBD) communication systems, but bi-directional links have DC current overhead associated with terminating both ends, resulting in poor power efficiency in low-activity scenarios. In applications where power needs to scale with activity rate, unidirectional complementary metal-oxide-semiconductor (CMOS) links with unterminated lines are still popular. However, such links have large switching noise at the transmitter (TX).

In at least some embodiments, an Inverter Short-Reach AC-Coupled Unidirectional (ISR-ACUD) link is based on transmitting only the bits transitions, hence removing the DC current overhead. The signal communication can be realized with small signal amplitude to reduce dynamic power consumption and simultaneous switching noise, which is associated with traditional unidirectional CMOS links with unterminated lines. In the ISR-ACUD architecture, the transmitter sends non-return to zero (NRZ) data through a small on-chip capacitor into the data channel or line. Because the TX side only sends the transitions in the data, the link may need to use a DC restoration mechanism at the RX side.

In other embodiments, similar circumstances and need can also arise in other short-reach, AC-coupled links such as ground-referenced signaling (GRS) links, low latency interface (LLI) links, and low power interface (LPI) links, the latter of which are chip-to-chip interconnects often used in systems where low power consumption and low latency are design goals. These interfaces are often seen in mobile and embedded systems, but their principles can be adapted or serve as inspiration for other high-performance domains. Some specific examples of these interfaces employed by Nvidia®, for example, include NVLink™, High-Bandwidth Interconnect (HBI), and Die-to-Die (D2D) interconnects. Thus, ISR-ACUD architecture is referenced herein to provide examples of how a variety of AC-coupled unidirectional links can operate.

In an ISR-ACUD link with a clock-forwarding scheme, according to some embodiments, the clocks are forwarded from the TX side to the RX side and used to sample the transmitted data in the RX side. Since a clock pattern and a random data pattern can experience different delays in the RX data path (i.e., due to the clock signal operating at a higher frequency for sampling and thus incurring different delays), the data RX circuit should compensate for skew between the clock and data signals to allow correct sampling of the data in RX samplers of the RX circuit. One approach of compensating for this skew is adding a configurable delay line over the clock path and data path so that different delay can be added for each, e.g., so that the original skew between clock and data paths are canceled. The usage of delay lines, however, adds additional power-consumption wasted both in the clock path and data path, adds more jitter in both paths, and can be susceptible to supply voltage and temperature variations.

Aspects and embodiments of the present disclosure address the above deficiencies and others in an AC-coupled unidirectional link (and other short-reach, AC-coupled links), by employing DC restoration with an embedded synchronization mechanism between clock and data signals within an ISR-ACUD (or other short-reach) communication system that avoids the necessity of using multiplexed delay lines in the clock path and the data path. The disclosed synchronization architecture can be easily calibrated and comparing the sampling phase of the clock to the phase of the data can be automatically calibrated. These and other advantages will be apparent to those skilled in the art of AC-coupled unidirectional links and other short-reach links, as will be discussed hereinafter.

For example, as the delay of inverter strings (in each of the clock RX and data RX circuits) is proportional to the voltage swing on input signals to these inverter strings, relative delays between the clock path and data path can cause a phase shift between the clock signal and data signal at the sampling point, which can cause timing errors which degrade the performance of the receiver. To synchronize the data and clock signals, the peak-to-peak amplitude of data input terminal (or B_{pad}) inputs can be calibrated to match the amplitude of the input clock signal (CKRᵢₙ). This can be done by adjusting the analog voltages inside the DC restoration mechanism of the data RX circuit, such that the data signal reaches the same DC voltage rails as does the clock signal.

In at least some embodiments, an example of a disclosed system includes a data channel of a short-reach AC-coupled unidirectional link. In embodiments, the data channel carries a data signal from a processing core coupled to the TX side of the link. The system can also include a clock channel of the short-reach AC-coupled unidirectional link. In embodiments, the clock channel carries a clock signal from the processing core, e.g., forwarded across the link. The system and/or a device embedded in the system can include clock detection circuitry coupled to the clock channel. In embodiments, the clock detection circuitry detects, at transitions of the clock signal, a first maximum value and a first minimum value of common mode-based amplitudes of the clock signal.

The system or device can further include a data RX circuit coupled to the clock detection circuitry and the data channel. In embodiments, the data RX circuit (e.g., using DC restoration circuitry) is configured to receive the data signal from the data channel and impose (e.g., force, limit, cause to match) a second maximum value and a second minimum value on bit transitions of the data signal based on, respectively, the first maximum value and the first minimum value obtained from the clock signal. The data RX circuit can further sample the data signal using the clock signal.

In some embodiments, to impose the second maximum value and the second minimum value on the bit transitions of the data signal, the data RX circuit causes the second maximum value to match the first maximum value and the second minimum value to match the first minimum value. By substantially matching the maximum and minimum amplitude values of the (analog) data signal to maximum and minimum common-mode amplitude values, respectively, of the forwarded clock signal, the disclosed circuit, device, or system matches (e.g., synchronizes) the delay of the clock signal to delay of the data signal. Thus, when the streaming data signal is sampled, the data RX circuit samples the data signal at the correct locations and accurately detects received data.

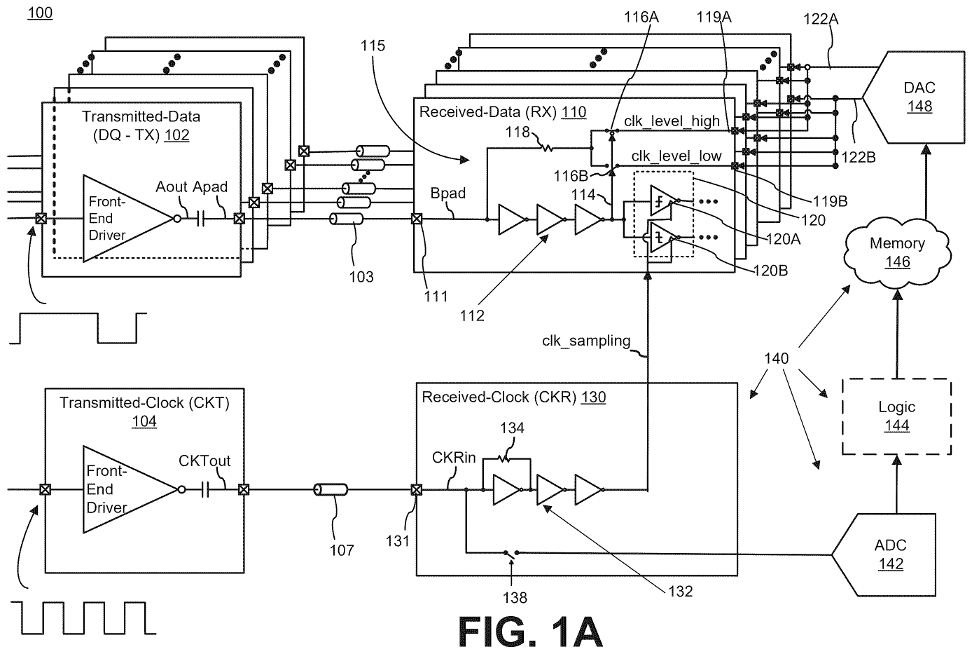

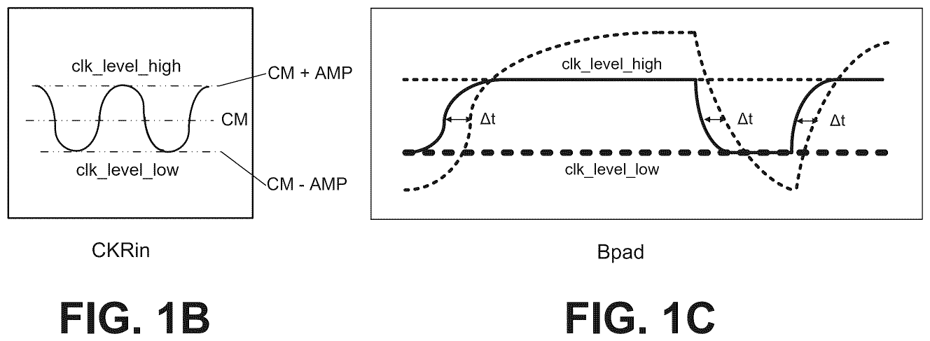

FIG. 1A is a schematic block diagram of an example system 100 composed of an AC-coupled unidirectional link employing circuitry for synchronizing amplitudes of data and clock signals for purposes of DC restoration before data sampling according to various embodiments. FIG. 1B is a diagram of the clock signal having the maximum value (clk_level_high) and minimum value (clk_value_low) of common mode-based amplitudes detected for use in forcing the amplitudes of the data signal according to some embodiments.

In such embodiments, the system 100 includes sets of data transmission (TX) circuits 102 (or data queue (DQ)-TX circuits) and data RX circuits 110 (or DQ-RX circuits) configured as transmitter-receiver (or transceiver) pairs coupled to each other over a data channel 103. While multiple transmitter-receiver pairs can exist in the system 100 as part of interconnects between one or more chips disposed on one or more dies, the discussion herein will be simplified to discuss a single transmitter-receiver pair that is representative of the disclosed embodiments and implementations of an AC-coupled unidirectional (or other such short-reach) link.

In embodiments, the system 100 thus includes the data channel 103 of a short-reach AC-coupled unidirectional link, e.g., a combination of the data TX circuit 102 and the data RX circuit 110. In embodiments, the data channel 103 carries a data signal from a processing core (not illustrated) that passes the data through the data TX circuit 102. In some embodiments, the system 100 also includes a clock TX circuit 104 that forwards a clock signal (CKTout) that is transmitted over a clock channel 107. The clock channel 107 can thus be configured to carry the clock signal (CKTout) generated by the processing core to an RX side of the link.

In some embodiments, the system 100 includes a clock RX circuit 130 coupled to the clock channel 107 to receive the forwarded clock signal (CKTout) from the clock TX circuit 104. In this embodiment, the clock signal (CKTout) can be a single-ended clock signal, for example. The system 100 can further include clock detection circuitry 140 coupled to the clock channel 107. In some embodiments, the clock detection circuitry 140 is configured to detect, at transitions of the clock signal, a first maximum value (clk_level_high) and a first minimum value (clk_level_low) of common mode-based amplitudes of the clock signal (see FIG. 1B), as will be discussed in more detail. As illustrated in FIG. 1B, common mode-based amplitudes include a common mode voltage level (CM) along with a positive or negative amplitude value. Thus, the first maximum value can be expressed as CM plus a clock amplitude (CM+AMP) and the first minimum value can be expressed as CM minus the clock amplitude (CM-AMP).

In various embodiments, the clock RX circuit 130 includes an input terminal 131 to receive the clock signal transmitted across the AC-coupled unidirectional link. The clock RX circuit 130 can further include a series of inverters 132 coupled between the input terminal 131 and one or more samplers of the data RX circuit 110, which will be discussed in more detail. The series of inverters 132 can provide some amplification and polarity control in the clock signal. Further, a resister 134 may provide a voltage feedback path across one or more inverters of the series of the inverters 132. The clock RX circuit 130 can further include a clock detect switch 138 coupled between the input terminal 131 and an analog-to-digital converter (ADC) 142 of the clock detection circuitry 140 that can be closed when detecting the maximum and minimum values of the common mode-based amplitude of the clock signal (CKR).

In some embodiments, the clock detection circuity 140 includes the ADC 142, optional detection logic 144, memory 146, and a digital-to-analog converter (DAC) 148. The ADC 142 can be configured to sample the clock signal to determine, as digital values, a first maximum amplitude value and a first minimum amplitude value, e.g., functioning similar to a peak-to-peak detector. For example, the ADC 142 can sample the clock signal at different phases of its cycle to generate digital words representing the maximum digital values (Vmax_digital) and minimum digital values (Vmin_digital) of measured amplitudes. The ADC 142 can further store, in the memory 146, the first maximum amplitude value and the first minimum amplitude value of the clock signal at each sampled location. In some embodiments, the logic 144 is configured to determine which of detected digital amplitude values to identify as the first minimum amplitude value and the first maximum amplitude value, although some ADCs can also perform this determination and thus the logic 144 is optional. In embodiments, the memory 146 is volatile memory, non-volatile memory (such as storage or permanent memory), can be dedicated fuses or registers, or a combination thereof.

In at least some embodiments, the DAC 148 retrieves, from the memory 146, the first maximum amplitude value and the first minimum amplitude value. The DAC 148 can further convert the first maximum amplitude value to the first maximum value for the data RX circuit 110 and convert the first minimum amplitude value to the first minimum value for the data RX circuit 110. The first maximum value can be passed over a first clock line 122A and the first minimum value can be passed over a second clock line 122A to input clock terminals of the data RX circuit 110.

In embodiments, the data RX circuit 110 includes an input terminal 111 coupled to the data channel 103, one or more samplers 120 (e.g., a first sampler 120A and a second sampler 120B) to sample the data signal, and a series of inverters 112 coupled between the input terminal 111 and the one or more samplers 120. The series of inverters 112 may provide amplification to the data signal, impose a delay on the data signal that depends on the DC level of the data signal, and determine polarity of the data signal to be sampled by the one or more samplers 120.

In some embodiments, the data RX circuit 110 further includes DC restoration circuitry 115 that causes the second maximum value and the second minimum value of bit transitions of the data signal to match the first maximum value and the first minimum value of the clock signal, respectively, which were received over the first clock line 122A and the second clock line 122B, respectively. In embodiments, therefore, the first maximum value and the first minimum value are DC analog levels of the clock signal and the second maximum value and the second minimum value are corresponding DC analog levels of the data signal. FIG. 1C is a diagram of an incoming data signal, at an input terminal of the data RX circuit 110, having imposed the maximum value and the minimum value of amplitudes according to some embodiments. As can be seen, the data signal (in dashed lines) being received at the input terminal 111 can be an NRZ signal with a high value and a low value not necessarily corresponding to 1 and 0, respectively. When the maximum value and the minimum value are imposed on the DC levels of the bit of the data signal, small changes in time (Δt) are also imposed on bit transitions, which are intended to synchronize with transitions in the clock signal.

With additional reference to FIG. 1A, the DC restoration circuitry 115 can include a first switch 116A coupled to a first terminal 119A. In embodiments, the first terminal 119A receives the first maximum value from the clock detection circuitry 140. The DC restoration circuitry 115 can include a second switch 116B coupled to a second terminal 119B. In embodiments, the second terminal 119B receives the first minimum value from the clock detection circuitry 140. In embodiments, these first maximum value and first minimum value are analog values that directly influence propagation delay of the data signal from the input terminal 111 to a bias control node coupled to an output of the series of inverters 112.

In embodiments, the DC restoration circuitry 115 further includes a resistor 118 coupled between the first switch 116A and the second switch 116B and the input terminal 111. In embodiments, an output of an inverter of the series of inverters 112 includes a clock level control signal 114 to activate one of the first switch 116A or the second switch 116B while deactivating the other of the first switch 116A and the second switch 116B within a negative feedback loop. In this way, the clock level control signal 114 alternates between imposing the maximum value and the minimum value on the incoming data signal, as is illustrated by the solid line in FIG. 1C.

In embodiments, the resistor 118 helps attenuate switching noise at the input terminal 111 that is generated by the clock level control signal 114. For example, the clock level control signal 114 can have a full rail-to-rail amplitude, such as from zero (or GND) to supply voltage (Vdd) to control the first switch 116A and the second switch 116B. The clock level control signal 114 also contains the data path information and is sampled by the forwarded-clock inside the samplers 120.

In embodiments, as discussed, the series of inverters 112 provides some amplification to the data signal. If there is a change to provide an even number of inverters, the system 100 could change the polarity of clock level control signal 114 that controls the switches 116A and 116B. The first switch 116A can be a p-type MOS (or PMOS) switch and the second switch 116B can be an n-type MOS (or NMOS) switch, although these can be swapped with changing polarity of clock level control signal 114 (e.g., with even number of inverters).

In some embodiments, for example, if the data signal at the input terminal 111 is low, the clock level control signal 114 goes to supply voltage (logical “1”), then the second switch 116B conducts and the first switch 116A is opened. This results in a clk_level_low signal at the input terminal 111. In embodiments, if the input terminal 111 input is high, the clock level control signal 114 goes to ground (logical “0”), then the first switch 116A conducts and the second switch 116B is opened. This results in a clk_level_high signal at input terminal 111. In this way, the DC restoration circuitry 115 helps drive the input terminal 111 data signal between analog voltage levels, thereby controlling (or locking in) the DC levels between the input NRZ signal at the input terminal 111.

In embodiments, the DC restoration circuitry 115 also helps keep the output to the samplers 120 consistent (no glitch to some undefined high-level or low-level voltages) even when the received data bits stay at zero or one (same value) for a long time. For example, glitches could occur from a leakage voltage and/or from drifting voltage at input terminal 111. Having a consistent amplitude at the input terminal 111 also helps keep delay consistent between input terminal 111 and the samplers 120, which helps synchronize data bit transitions with the forwarded clock signal. Thus, in this way, it can be helpful to mimic the DC-restoration mechanism on the clock side as well, enabling the sampling phase of the clock signal at the samplers 120 to be aligned to the data signal as well.

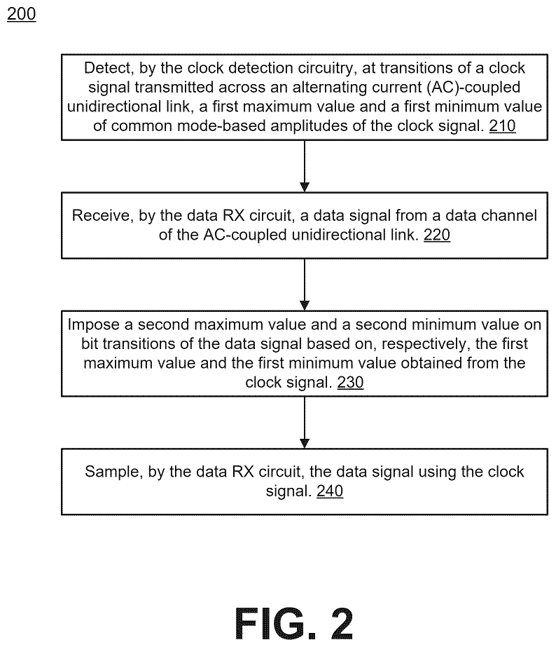

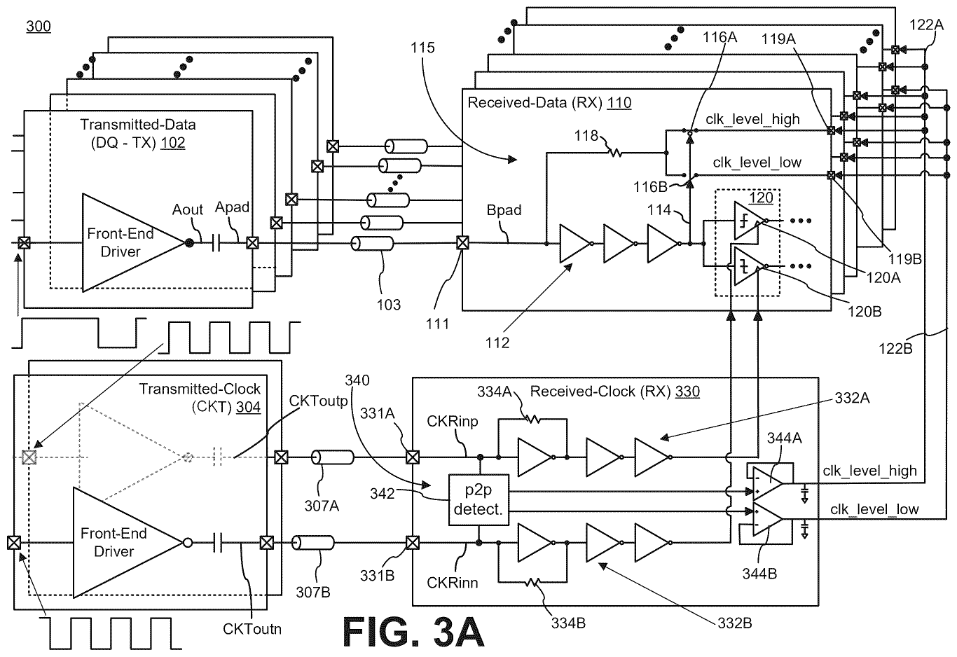

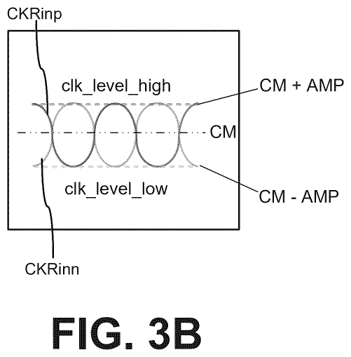

FIG. 2 is a flow chart of a method 200 of operating a circuit for synchronizing maximum and minimum values of common mode-based amplitudes between the clock and data signals when performing DC restoration before data sampling according to various embodiments. In various embodiments, the method 200 is performed by processing logic of any of the circuitry of the AC-coupled unidirectional link of FIG. 1A or FIG. 3A. The processing logic can include hardware, firmware, or a combination thereof. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 210, the method 200 includes detecting, by the clock detection circuitry, at transitions of a clock signal transmitted across an alternating current (AC)-coupled unidirectional link, a first maximum value and a first minimum value of common mode-based amplitudes of the clock signal.

At operation 220, the method 200 includes receiving, by the data RX circuit, a data signal from a data channel of the AC-coupled unidirectional link.

At operation 230, the method 200 includes imposing a second maximum value and a second minimum value on bit transitions of the data signal based on, respectively, the first maximum value and the first minimum value obtained from the clock signal.

At operation 240, the method 200 includes sampling, by the data RX circuit, the data signal using the clock signal.

FIG. 3A is a schematic block diagram of an example system 300 composed of an AC-coupled unidirectional link employing circuitry for synchronizing amplitudes of a data signal and a differential clock signal for purposes of DC restoration before data sampling according to alternative embodiments. FIG. 3B is a diagram of the clock signal having the maximum value and minimum value of common mode-based amplitudes detected for use in forcing the amplitudes of the data signal according to some embodiments.

As a variation to the system 100 of FIG. 1A, it is possible to employ a differential clock signal as the clock signal being forwarded from the processor core. Thus, the system 300 can include a clock TX circuit 304 that forwards, to the RX side, a differential clock signal having a first signal (e.g., positive clock signal or CKToutp) and a second signal (e.g., negative clock signal or CKToutn).

Thus, while the data path architecture may stay the same as discussed with reference to FIG. 1A, the example system 300 can include a clock RX circuit 330 configured to detect maximum values and minimum values of common mode-amplitudes of the differential clock signal that can be provided to the data RX circuit 110. The clock RX circuit 330 can include a first input terminal 331A coupled to a first clock channel 307A to receive a first signal of the differential clock signal, e.g., a positive input clock signal (CKRinp), from the clock TX circuit 304. In embodiments, the clock RX circuit 330 includes a second input terminal 331B coupled to a second clock channel 307B to receive a second signal of the differential clock signal, e.g., a negative input clock signal (CKRinn), from the clock TX circuit 304. As illustrated in FIG. 3B, the positive peak or maximum value of common mode-based amplitudes of the differential clock signal can be a common mode level (CM) plus a clock amplitude (CM+AMP) and a negative peak or minimum value of the common mode-based amplitudes of the differential clock signal can be the common mode level (CM) minus the clock amplitude (CM-AMP).

In various embodiments, the clock RX circuit 330 includes a first series of inverters 332A coupled to the first input terminal 331A to amplify the first signal (CKRinp) for the second sampler 120B. A first resister 334A may be connected as a negative feedback loop across one or more inverters of the first series of inverters 332A. In embodiments, the clock RX circuit 330 includes a second series of inverters 332B coupled to the second input terminal 331B to amplify the second signal (CKRinn) for the first sampler 120A. A second resister 334B may be connected as a negative feedback loop across one or more inverters of the second series of inverters 332B.

In some embodiments, the clock RX circuit 330 includes clock detection circuitry 340 coupled to the first input terminal 331A and the second input terminal 331B. The clock detection circuitry 340 can be configured to detect, at transitions of the clock signal, a first maximum value and a first minimum value of common mode-based amplitudes of the differential clock signal. For example, in embodiments, the clock detection circuitry 340 includes a peak-to-peak detector 342 coupled between the first input terminal 331A and the second input terminal 331B. In embodiments, the peak-to-peak detector 342 detects the first maximum value from the first signal and detects the first minimum value from the second signal of the differential clock signal.

In at least some embodiments, the clock detection circuity 340 further includes a first analog voltage buffer 344A, coupled to the peak-to-peak detector 342, to hold and drive the first maximum value (clk_level_high) to the data RX circuit 110. For example, the first analog voltage buffer 344A can hold and drive the first maximum value over first clock line 122A. The clock detection circuit 340 can further include a second analog voltage buffer 344B, coupled to the peak-to-peak detector 342, to hold and drive the first minimum value (clk_level_low) to the data RX circuit 110. For example, the second analog voltage buffer 344B can hold and drive the first minimum value over second clock line 122B. By providing, for a short period of time, the first maximum value on the first clock line 122A and the first minimum value on the second clock line 122B, the clock detection circuitry 340 can directly route the first maximum and minimum values of the common mode-based amplitudes of the differential clock signal to the data RX circuit 110 for use in sampling the data signal. In some embodiments, a sufficiently high-quality peak-to-peak detector 342 may be capable and holding and driving these first maximum and minimum values, and thus the first analog voltage buffer 344A and the second analog voltage buffer 344B could be considered optional.

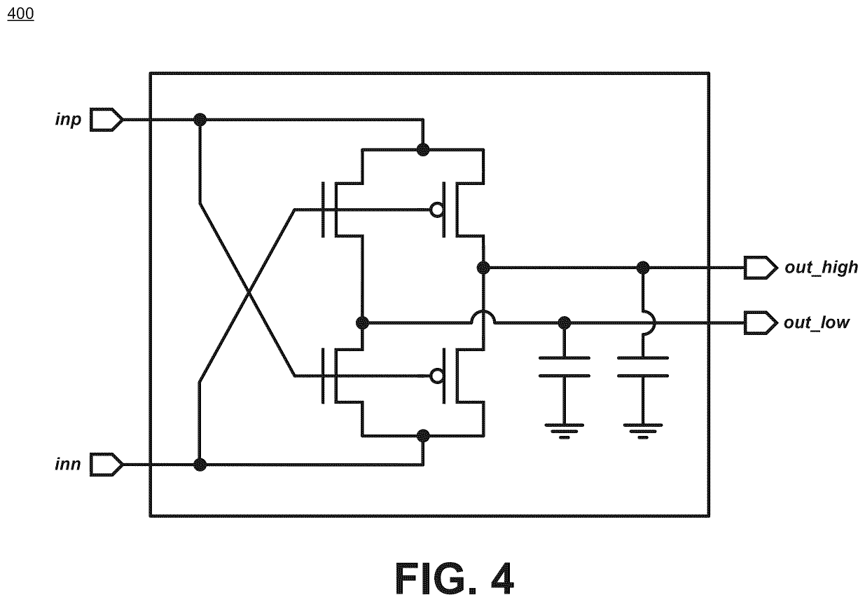

FIG. 4 is a schematic diagram of an example differential peak-to-peak detector 400 that can be employed in the example system of FIG. 3A according to at least one embodiment. For example, the peak-to-peak detector 342 can be the peak-to-peak detector 400 in some embodiments, which employs a set of cross-coupled CMOS inverters, as illustrated.

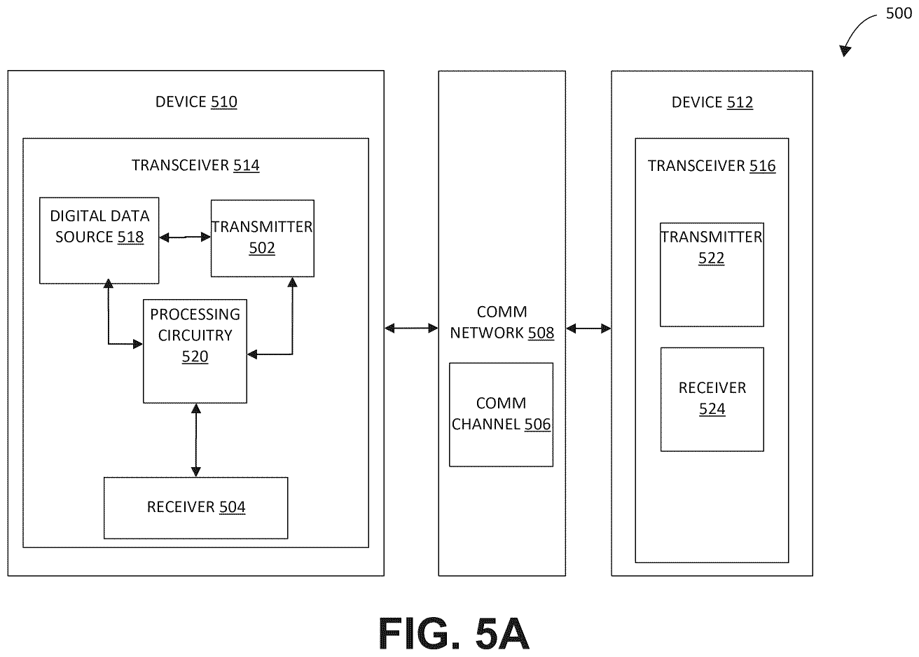

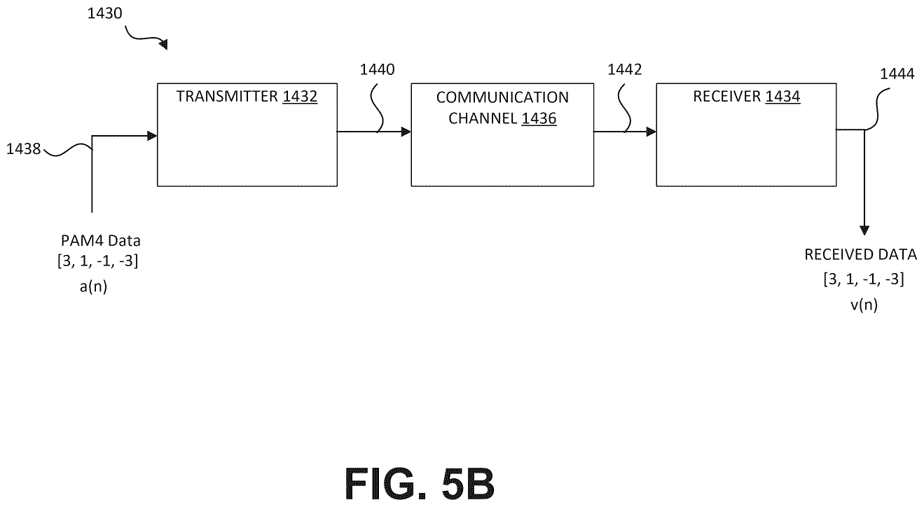

FIG. 5A illustrates an example communication system 500 in which the AC-coupled unidirectional (or short-reach) link operates according to at least one embodiment. The communication system 500 includes a device 510, a communication network 508 including a communication channel 506, and a device 512. In at least one embodiment, the devices 510 and 512 are integrated circuits of a Personal Computer (PC), a laptop, a tablet, a smartphone, a server, a collection of servers, or the like. In some embodiments, the devices 510 and 512 may correspond to any appropriate type of device that communicates with other devices also connected to a common type of communication network 508. According to embodiments, the transmitter 502 and 522 of devices 510 or 512 may correspond to transmitters of a Graphics Processing Unit (GPU), a switch (e.g., a high-speed network switch), a network adapter, a central processing unit (CPU), a data processing unit (DPU), etc.

Examples of the communication network 508 that may be used to connect the devices 510 and 512 include wires, conductive traces, bumps, terminals, optical fibers, or the like. In other embodiments, the communication network 508 can be a Peripheral Component Interconnect Express (PCIe) interconnect. PCIe is a high-speed interface standard used to connect various hardware components. It can be an interconnect for devices such as graphics cards (GPUs), solid-state drives (SSDs), network cards, and other peripherals. PCIe offers a scalable, high-speed, and point-to-point connection between devices, including CPUs, GPUs, memory, and the like. In other embodiments, the communication network 508 can be a high-speed interconnect, such as an interconnect that deploys the NVLink technology. The NVLink interconnect can be a GPU-GPU interconnect used between GPUs, a CPU-GPU interconnect between GPUs and CPUs, or an interconnect used between other devices. NVLink offers a higher bandwidth and lower latency than traditional PCIe connections, which are typically used in computing hardware. NVLink is especially useful in scenarios that require massive parallel processing, such as artificial intelligence (AI), machine learning, deep learning, high-performance computing (HPC), and data analytics. For example, in NVIDIA's DGX systems and high-end gaming or AI workstations, NVLink helps GPUs exchange data at speeds that are necessary for demanding tasks like real-time ray tracing or training neural networks. In one specific, but non-limiting example, the communication network 508 is a network that enables data transmission between the devices 510 and 512 using data signals (e.g., digital, optical, wireless signals), clock signals, or both. The embodiments described herein can be utilized in a system with a high-speed, scalable switch, such as a switch using the NVSwitch technology. NVSwitch is a high-speed, scalable switch developed by NVIDIA that facilitates data communication between multiple GPUs in a system, allowing them to work together more efficiently by providing high-bandwidth, low-latency interconnections. The NVSwitch serves as a central hub or high-bandwidth fabric that interconnects all the GPUs in a system, enabling each GPU to communicate with every other GPU quickly and efficiently. The NVSwitch can be coupled between other types of devices, such as CPUs, accelerators, memory, or the like. The NVSwitch can be used for tasks requiring intense computation and collaboration between multiple GPUs, such as AI model training, scientific simulations, and large-scale data processing. The embodiments described herein can be used in a high-performance computing system, such as a computing system modeled after NVIDIA's DGX systems, which are designed specifically for artificial intelligence (AI), deep learning, and high-performance computing (HPC) workloads. DGX systems are optimized for large-scale GPU computation and parallel processing, integrating multiple GPUs, high-bandwidth interconnects, and software frameworks tailored for AI and HPC tasks. In at least one embodiment, a system for high-speed network communication includes a processing unit, a network interface comprising a receiver or transceiver that is composed of an AC-coupled unidirectional (or short-reach) link as described herein. The processing unit can include a CPU, a GPU, a DPU, a network adapter, a network switch, an NVLink switch, or the like. 2436, as described herein.

Other examples for the communication network 508 can include other chip-to-chip or die-to-die interconnects, such as GRS, LPI (low power interface) or LLI (low latency interface).

The device 510 includes a transceiver 514 for sending and receiving signals, for example, data signals. The data signals may be digital or optical signals modulated with data or other suitable signals for carrying data.

The transceiver 514 may include a digital data source 518, a transmitter 2402, a receiver 504, and processing circuitry 520 that controls the transceiver 514. The digital data source 518 may include suitable hardware and/or software for outputting data in a digital format (e.g., in binary code and/or thermometer code). The digital data output by the digital data source 518 may be retrieved from memory (not illustrated) or generated according to input (e.g., user input). The transceiver 514 can include the AC-coupled unidirectional (or short-reach) link as described above with respect to FIG. 1A and FIG. 3A, e.g., includes sets of data TX circuits 102, data RX circuits 110, a clock TX circuit 104 or 304, and a clock RX circuit 130 or 330, depending on which device operates as a transmitter and which operates as receiver.

The transceiver 514 includes suitable software and/or hardware for receiving digital data from the digital data source 518 and outputting data signals according to the digital data for transmission over the communication network 508 to a transceiver 516 of device 512.

The receiver 504 of device 510 may include suitable hardware and/or software for receiving signals, for example, data signals from the communication network 508. For example, the receiver 504 may include components for receiving processing signals to extract the data for storing in a memory. In at least one embodiment, the transceiver 516 includes a transmitter 522 and receive 524. The transceiver 516 receives an incoming signal and samples the incoming signal to generate samples, such as using an analog-to-digital converter (ADC). The ADC can be controlled by a clock-recovery circuit (or clock recovery block) in a closed-loop tracking scheme. The clock-recovery circuit can include a controlled oscillator, such as a voltage-controlled oscillator (VCO) or a digitally-controlled oscillator (DCO) that controls the sampling of the subsequent data by the ADC. The transceiver 516 can include the AC-coupled unidirectional (or short-reach) link as described above with respect to FIG. 1A and FIG. 3A, e.g., includes sets of data TX circuits 102, data RX circuits 110, a clock TX circuit 104 or 304, and a clock RX circuit 130 or 330, depending on which device operates as a transmitter and which operates as receiver.

The processing circuitry 520 may comprise software, hardware, or a combination thereof. For example, the processing circuitry 520 may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory). Additionally or alternatively, the processing circuitry 520 may comprise hardware, such as an Application-Specific Integrated circuit (ASIC). Other non-limiting examples of the processing circuitry 520 include an Integrated Circuit (IC) chip, a CPU, A GPU, a DPU, a microprocessor, a Field-Programmable Gate Array (FPGA), a collection of logic gates or transistors, resistors, capacitors, inductors, diodes, or the like. Some or all of the processing circuitry 520 may be provided on a Printed Circuit Board (PCB) or collection of PCBs. It should be appreciated that any appropriate type of electrical component or collection of electrical components may be suitable for inclusion in the processing circuitry 520. The processing circuitry 520 may send and/or receive signals to and/or from other elements of the transceiver 514 to control the overall operation of the transceiver 514.

The transceiver 514 or selected elements of the transceiver 514 may take the form of a pluggable card or controller for the device 510. For example, the transceiver 514 or selected elements of the transceiver 514 may be implemented on a network interface card (NIC).

The device 512 may include a transceiver 516 for sending and receiving signals, for example, data signals over a communication channel 506 of the communication network 508. The channel 2406 can be PCIe, NVLink, Ethernet, InfiniBand, Ground Reference Signal (GRS), Chip-to-Chip (C2C), Die-to-Die (D2D), or the like. The same or similar structure of the transceiver 514 may be applied to transceiver 516, and thus, the structure of transceiver 516 is not described separately.

Although not explicitly shown, it should be appreciated that devices 510 and 512 and the transceiver 514 and transceiver 516 may include other processing devices, storage devices, and/or communication interfaces generally associated with computing tasks, such as sending and receiving data.

FIG. 5B illustrates a block diagram of an example communication system 530 in which the AC-coupled unidirectional (or short-reach) link operates according to at least one embodiment. In the example shown in FIG. 5B, a Pulse Amplitude Modulation level-4 (PAM4) modulation scheme is employed with respect to the transmission of a signal (e.g., digitally encoded data) from a transmitter (TX) 532 to a receiver (RX) 534 via a communication channel 536 (e.g., a transmission medium). The communication channel 2406 can be PCIe, NVLink, Ethernet, InfiniBand, GRS, C2C, D2D, or the like. In this example, the transmitter 532 receives an input data 538 (i.e., the input data at time n is represented as “a(n)”), which is modulated in accordance with a modulation scheme (e.g., PAM4) and sends the signal 540 a(n) including a set of data symbols (e.g., symbols-3,-1, 1, 3, where the symbols represent coded binary data). It is noted that while the use of the PAM4 modulation scheme is described herein by way of example, other data modulation schemes can be used in accordance with embodiments of the present disclosure, including for example, a non-return-to-zero (NRZ) modulation scheme, PAM3, PAM7, PAM8, PAM16, etc. For example, for an NRZ-based system, the transmitted data symbols consist of symbols-1 and 1, with each symbol value representing a binary bit. This is also known as a PAM level-2 or PAM2 system as there are 2 unique values of transmitted symbols. Typically, a binary bit 0 is encoded as-1, and a bit 1 is encoded as 1 as the PAM2 values.

In the example shown, the PAM4 modulation scheme uses four (4) unique values of transmitted symbols to achieve higher efficiency and performance. The four levels are denoted by symbol values-3,-1, 1, 3, with each symbol representing a corresponding unique combination of binary bits (e.g., 00, 01, 10, 11).

The communication channel 536 is a destructive medium in that the channel acts as a low pass filter which attenuates higher frequencies more than it attenuates lower frequencies, introduces inter-symbol interference (ISI) and noise from cross talk, from power supplies, from Electromagnetic Interference (EMI), or from other sources. The communication channel 536 can be over serial links (e.g., a cable, PCB traces, copper cables, optical fibers, or the like), read channels for data storage (e.g., hard disk, flash solid-state drives (SSDs), high-speed serial links, deep space satellite communication channels, applications, or the like. The receiver (RX) 534 receives an incoming signal 542 over the communication channel 536. The receiver 534 can output a received signal 544, “v(n),” including the set of data symbols (e.g., symbols −3,−1, 1, 3, wherein the symbols represent coded binary data).

In at least one embodiment, the transmitter 532 can be part of a SerDes IC. The SerDes IC can be a transceiver that converts parallel data to serial data and vice versa. The SerDes IC can facilitate transmission between two devices over serial streams, reducing the number of data paths, wires/traces, terminals, etc. The receiver 534 can be part of a SerDes IC. The SerDes IC can include a clock-recovery circuit. The clock-recovery circuit can be coupled to an ADC and an equalization block. In another embodiment, the SerDes IC can include additional equalization block before a symbol detector.

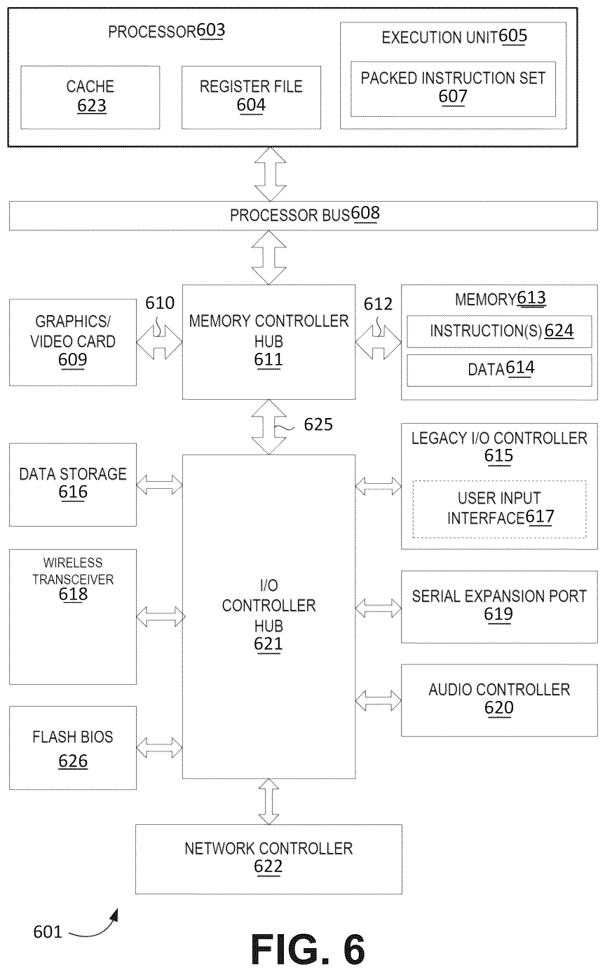

FIG. 6 illustrates an example computer system 601, including an error correction circuit 630, in accordance with at least some embodiments. In at least one embodiment, computer system 601 may be a system with interconnected devices and components, an SOC, or some combination. In at least one embodiment, computer system 601 is formed with a processor 603 that may include execution units to execute an instruction. In at least one embodiment, computer system 601 may include, without limitation, a component, such as a processor 603, to employ execution units including logic to perform algorithms for processing data. In at least one embodiment, computer system 601 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 601 may execute a version of WINDOWS' operating system available from Microsoft Corporation of Redmond, Wash., although other operating systems (UNIX and Linux, for example), embedded software, and/or graphical user interfaces, may also be used.

In at least one embodiment, computer system 601 may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (DSP), an SoC, network computers (“NetPCs”), set-top boxes, network hubs, wide area network (“WAN”) switches, or any other system that may perform one or more instructions. In an embodiment, computer system 601 may be used in devices such as graphics processing units (GPUs), network adapters, central processing units, and network devices such as switches (e.g., a high-speed direct GPU-to-GPU interconnect such as the NVIDIA GH100 NVLINK or the NVIDIA Quantum 2 64 Ports InfiniBand NDR Switch).

In at least one embodiment, computer system 601 may include, without limitation, processor 603 that may include, without limitation, one or more execution units 605 that may be configured to execute a Compute Unified Device Architecture (“CUDA”) (CUDA® is developed by NVIDIA Corporation of Santa Clara, CA) program. In at least one embodiment, a CUDA program is at least a portion of a software application written in a CUDA programming language. In at least one embodiment, computer system 601 is a single processor desktop or server system. In at least one embodiment, computer system 601 may be a multiprocessor system. In at least one embodiment, processor 603 may include, without limitation, a CISC microprocessor, a RISC microprocessor, a VLIW microprocessor, and a processor implementing a combination of instruction sets, or any other processor device, such as a digital signal processor, for example. In at least one embodiment, processor 603 may be coupled to a processor bus 608 that may transmit data signals between processor 603 and other components in computer system 601.

In at least one embodiment, processor 603 may include, without limitation, a Level 1 (“L1”) internal cache memory (“cache”) 623. In at least one embodiment, processor 603 may have a single internal cache or multiple levels of internal cache. In at least one embodiment, cache memory may reside external to processor 603. In at least one embodiment, processor 603 may also include a combination of both internal and external caches. In at least one embodiment, a register file 604 may store different types of data in various registers including, without limitation, integer registers, floating point registers, status registers, and instruction pointer register.

In at least one embodiment, execution unit 605, including, without limitation, logic to perform integer and floating point operations, also resides in processor 603. Processor 603 may also include a microcode (“ucode”) read only memory (“ROM”) that stores microcode for certain macro instructions. In at least one embodiment, execution unit 605 may include logic to handle a packed instruction set 607. In at least one embodiment, by including packed instruction set 607 in an instruction set of a general-purpose processor 603, along with associated circuitry to execute instructions, operations used by many multimedia applications may be performed using packed data in a general-purpose processor 603. In at least one embodiment, many multimedia applications may be accelerated and executed more efficiently by using full width of a processor's data bus for performing operations on packed data, which may eliminate a need to transfer smaller units of data across a processor's data bus to perform one or more operations one data element at a time.

In at least one embodiment, execution unit 606 may also be used in microcontrollers, embedded processors, graphics devices, DSPs, and other types of logic circuits. In at least one embodiment, computer system 601 may include, without limitation, a memory 613. In at least one embodiment, memory 613 may be implemented as a DRAM device, an SRAM device, flash memory device, or other memory devices. Memory 613 may store instruction(s) 624 and/or data 614 represented by data signals that may be executed by processor 603.

In at least one embodiment, a system logic chip may be coupled to a processor bus 608 and memory 613. In at least one embodiment, the system logic chip may include, without limitation, a memory controller hub (“MCH”) 611 and processor 603 may communicate with MCH 611 via processor bus 608. In at least one embodiment, MCH 611 may provide a high bandwidth memory path 612 to memory 613 for instruction and data storage and for storage of graphics commands, data, and textures. In at least one embodiment, MCH 611 may direct data signals between processor 603, memory 613, and other components in computer system 601 and may bridge data signals between processor bus 608, memory 613, and a system I/O 625. In at least one embodiment, a system logic chip may provide a graphics port for coupling to a graphics controller. In at least one embodiment, MCH 611 may be coupled to memory 613 through high bandwidth memory path 612, and graphics/video card 609 may be coupled to MCH 611 through an Accelerated Graphics Port (“AGP”) interconnect 610.

In at least one embodiment, computer system 601 may use system I/O 625 that is a proprietary hub interface bus to couple MCH 611 to I/O controller hub (“ICH”) 621. In at least one embodiment, ICH 621 may provide direct connections to some I/O devices via a local I/O bus. In at least one embodiment, a local I/O bus may include, without limitation, a high-speed I/O bus for connecting peripherals to memory 613, a chipset, and processor 603. Examples may include, without limitation, an audio controller 620, a firmware hub (“flash BIOS”) 726, a wireless transceiver 618, a data storage 616, a legacy I/O controller 615 containing a user input interface 617, a keyboard interface, a serial expansion port 619, such as a USB, and a network controller 622. Data storage 616 may comprise a hard disk drive, a floppy disk drive, a CD-ROM device, a flash memory device, or other mass storage device. In various embodiments, communication between any two short-reach coupled components (such as die-to-die) can include the AC-coupled unidirectional link as described herein.

In at least one embodiment, FIG. 6 illustrates a system, which includes interconnected hardware devices or “chips.” In at least one embodiment, FIG. 6 may illustrate an example SoC. In at least one embodiment, devices illustrated in FIG. 6 may be interconnected with proprietary interconnects, standardized interconnects (e.g., PCIe), or some combination thereof. In at least one embodiment, one or more components of system 602 are interconnected using compute express link (“CXL”) interconnects.

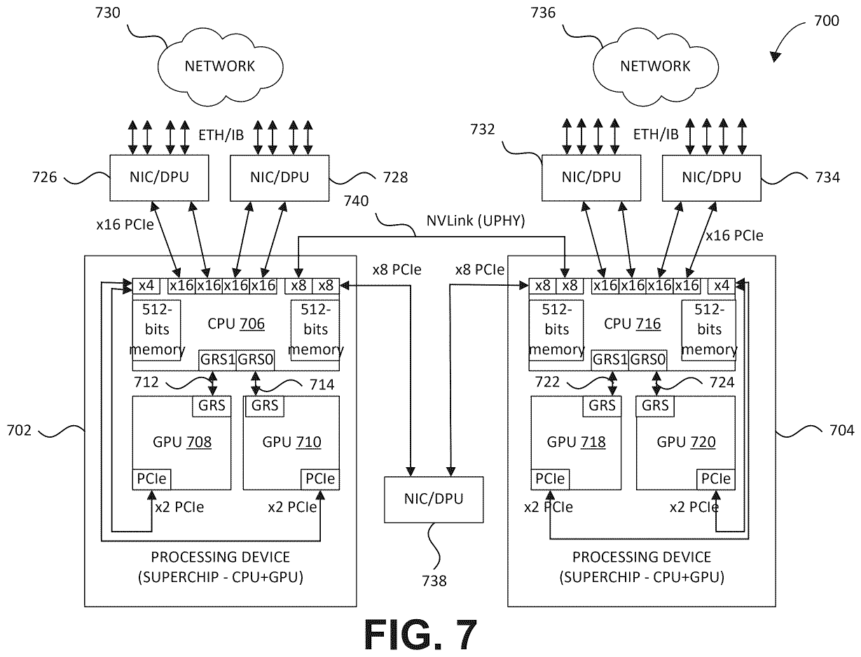

FIG. 7 is a block diagram of a computing system 700 having two processing devices coupled to each other and multiple networks according to at least one embodiment. The computing system 700 is designed with multiple integrated circuits (referred to as processing devices), where each integrated circuit includes a CPU and two GPUs, forming a powerful and flexible architecture. These processing devices are interconnected via an NVLink (or other high-speed interconnect), enabling high-speed communication between the processing devices, and are also connected through a Network Interface Card (NIC) or Data Processing Unit (DPU) to ensure efficient data transfer across the computing system 700. The coupling of processing devices through NVLink allows for seamless data exchange and parallel processing, enhancing overall computational performance. Additionally, these processing devices are connected to multiple networks through one or more network interface cards (NICs) or DPUs, enabling the system to handle complex, multi-network tasks with high bandwidth and low latency. This configuration makes the computing system 700 highly suitable for demanding applications that require significant processing power, such as artificial intelligence (AI), machine learning (ML), and data-intensive computing, while ensuring robust connectivity and scalability across various networked environments. The integrated circuits of the computing system 700 can include one or more CPUs and one or more GPUs. An example architecture of a multi-GPU architecture is illustrated in FIG. 7.

As illustrated in FIG. 7, the computing system 700 includes a processing device 702 with a multi-GPU architecture. In particular, the processing device 702 includes a CPU 706, a GPU 708, and a GPU 710. The CPU 706 can be coupled to the GPU 708 via an die-to-die (D2D) or chip-to-chip (C2C) interconnect 712, such as a Ground-Referenced Signaling interconnect (GRS interconnect). The CPU 706 can be coupled to the GPU 710 via a D2D or C2C interconnect 714. The CPU 706 can also couple to the GPU 708 and GPU 710 via PCIe interconnects. The CPU 706 can be coupled to one or more network interface cards (NICs) or data processing units (DPUs), which are coupled to one or more networks. For example, as illustrated in FIG. 7, the CPU 706 is coupled to a first NIC/DPU 726, which is coupled to a network 730. The CPU 706 is also coupled to a second NIC/DPU 728, which is coupled to the network 730. The NIC/DPU 726 and NIC/DPU 728 can be coupled to the network 730 over Ethernet (ETH) or InfiniBand (IB) connections.

The computing system 700 also includes a processing device 704 with a multi-GPU architecture. In particular, the processing device 704 includes a CPU 716, a GPU 718, and a GPU 720. The CPU 716 can be coupled to the GPU 718 via an D2D or C2C interconnect 722. The CPU 716 can be coupled to the GPU 720 via a D2D or C2C interconnect 724. The CPU 716 can also couple to the GPU 718 and GPU 720 via PCIe interconnects. The CPU 716 can be coupled to one or more NICs or DPUs, which are coupled to one or more networks. For example, as illustrated in FIG. 7, the CPU 716 is coupled to a first NIC/DPU 732, which is coupled to a network 736. The CPU 716 is also coupled to a second NIC/DPU 734, which is coupled to the network 736. The NIC/DPU 732 and NIC/DPU 734 can be coupled to the network 736 over Ethernet (ETH) or InfiniBand (IB) connections.

In at least one embodiment, the processing device 702 and the processing device 704 can communication with each other via a NIC/DPU 738, such as over PCIe interconnects. The processing device 702 and processing device 704 can also communicate with each other over a high-bandwidth communication interconnects 740, such as an NVLink interconnect or other high-speed interconnects. The NIC/DPUs of FIG. 7 can be the various embodiments of the DPUs described herein. The error correction circuit 140 can be implemented in any receiver device of any of the devices described herein.

In at least one embodiment, the computing system 700 is used for high-speed network communication and includes a processing unit (e.g., CPU 706, GPU 708, GPU 710, CPU 716, GPU 718, GPU 720, NIC/DPU 726, NIC/DPU 728, NIC/DPU 732, NIC/DPU 734, or NIC/DPU 738), and a network interface coupled to the processing unit. The network interface can include the operations and functionality of the DPUs described herein.

In at least one embodiment, the computing system 700 includes a host device and an auxiliary device. The auxiliary device includes a device memory and a processor, communicably coupled to the device memory. The auxiliary device performs the operations described herein with respect to FIG. 1A to FIG. 4. The auxiliary device can include a GPU. The auxiliary device can include a DPU. The auxiliary device can include a DPU. The auxiliary device can include accelerator hardware.

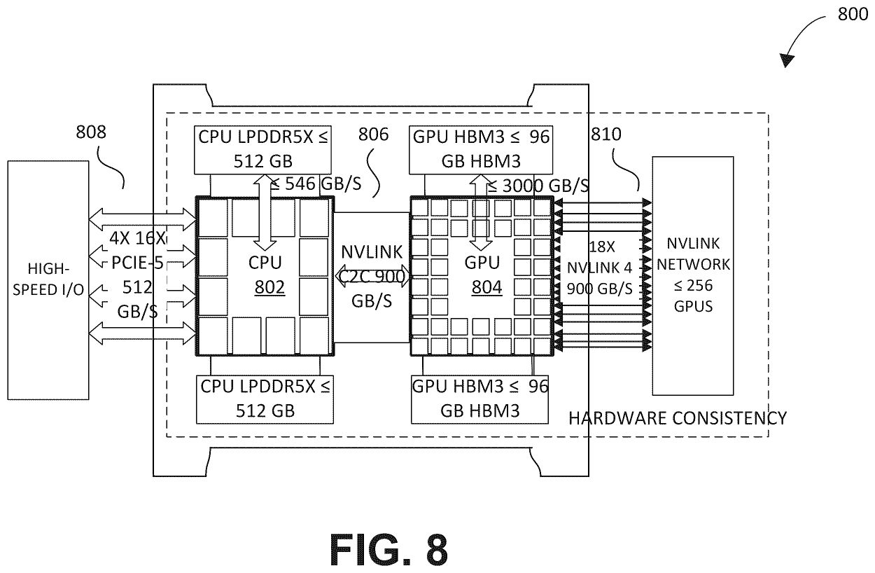

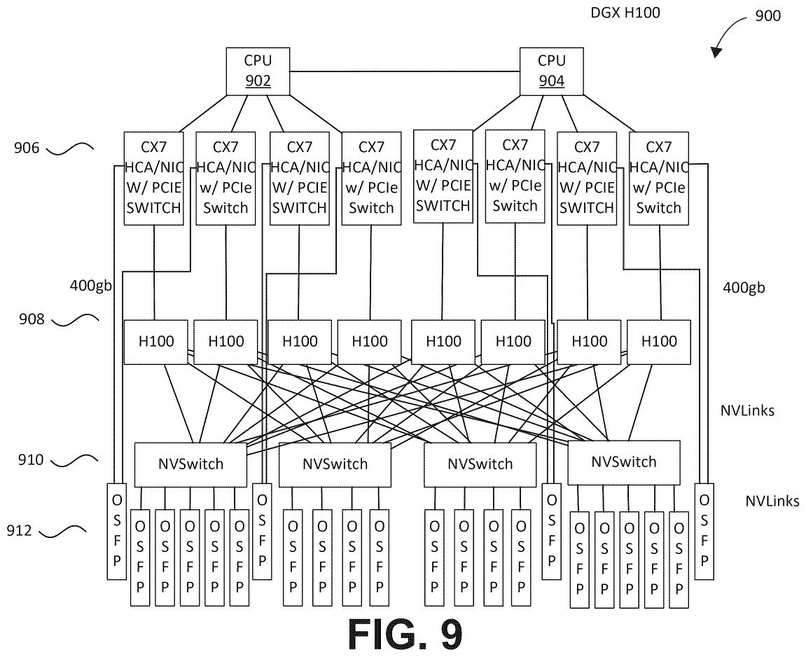

FIG. 8 is a block diagram of a computing system 800 having a CPU 802 and a GPU 804 in a single integrated circuit according to at least one embodiment. The computing system 800 can be a highly integrated design where a CPU 802 and GPU 804 are connected on a single integrated circuit, utilizing an NVLink C2C (Chip-to-Chip) interconnect 806 to enable fast, low-latency communication between the two processing units. This close integration allows for efficient data transfer and parallel processing between the CPU 802 and GPU 804, optimizing performance for complex computational tasks. The GPU elements within the computing system 800 can be interconnected using an NVLink network, allowing for scalability up to 256 GPU elements, creating a powerful, unified processing environment ideal for large-scale AI, ML, and high-performance computing applications. The NVLink network can be a GPU fabric of high-bandwidth communication interconnects 810. Additionally, the computing system 800 can be designed to interface with a high-speed I/O through PCIe interconnects 808, ensuring rapid data transfer to and from external devices, further enhancing the system's capabilities in handling data-intensive tasks and providing robust connectivity to peripheral components. It should be noted that the C2C interconnects 806 can be considered D2D interconnects since the CPU 802 and the GPU 804 are located on the same integrated circuit. The integrated circuit can include CPU memory (also referred to as main memory) and GPU memory, which are accessible by the CPU 802 and the GPU 804, respectively, over high-speed interconnects. The computing system 800 can bring together performance of the GPU 804 with the versatility of the CPU 802. The CPU 802 can be connected with a high-bandwidth and memory coherent C2C interconnects 806 in a single integrated circuit. The computing system 800 can support a link switch system.

The computing system 800 can include the error correction circuit 140 used for the various embodiments described herein with respect to FIG. 1A to FIG. 4. The error correction circuit 140 can be implemented in any receiver device of any of the devices described herein.

In at least one embodiment, the computing system 800 is used for high-speed network communication and includes a processing unit, and a network interface coupled to the processing unit. The network interface can include the operations and functionality of the DPUs described herein.

In at least one embodiment, the computing system 800 includes a host device and an auxiliary device. The auxiliary device includes a device memory and a processor, communicably coupled to the device memory. The auxiliary device performs the operations described herein with respect to FIG. 1 to FIG. 9. The auxiliary device can include a GPU. The auxiliary device can include a DPU. The auxiliary device can include a DPU. The auxiliary device can include accelerator hardware.

FIG. 9 is a block diagram of a computing system 900 having tensor core GPUs 908 according to at least one embodiment. The computing system 900 can be a DGX H100 system, which is a high-performance computing platform designed to meet the demands of AI, ML, and deep learning (DL) workloads. The computing system 900 can include multiple tensor core GPUs 908 (e.g., NVIDIA H100 Tensor Core GPUs). The tensor core GPUs 908 can each be one of the integrated circuits described above with respect to FIG. 1A or FIG. 3A. The tensor core GPUs 908 can be optimized for AI/ML/DL applications, offering exceptional performance for deep learning training, inference, and high-performance computing tasks. The tensor core GPUs 908 within the computing system 900 are interconnected using high-speed communication interfaces like NVLinks, enabling rapid data transfer between them, which is crucial for handling large-scale AI models and datasets with low latency. This computing system 900 is designed for scalability, allowing for the integration of additional GPUs as required, making it versatile enough for research, development, and deployment in data centers for production AI workloads. Each GPU is equipped with Tensor Cores, specialized processing units that accelerate matrix operations, a fundamental component of AI and deep learning algorithms. These Tensor Cores enable the system to perform mixed-precision calculations efficiently, balancing speed and accuracy. Given the power consumption and heat generation of multiple tensor core GPUs 908, the computing system 900 can include advanced cooling solutions and power management features to ensure safe operation while maintaining peak performance. It is supported by a comprehensive software ecosystem, including NVIDIA's CUDA programming model, AI frameworks like TensorFlow and PyTorch, and other HPC and AI software tools, which enable developers and researchers to harness the full power of the tensor core GPUs 908 for their specific applications. The computing system 900 is ideally suited for large-scale AI model training, real-time inference, scientific simulations, data analytics, and other compute-intensive tasks that require massive parallel processing power.

The tensor core GPUs 908 can be coupled to multiple CPUs, such as CPU 902 and CPU 904, using switches 906 (e.g., CX7 HCA/NIC with PCIe switch). The tensor core GPUs 908 can be coupled to each other via switches 910 (e.g., NVSwitches). The switches 906 and switches 910 can be coupled to high-speed transceiver modules 912. The high-speed transceiver modules 912 can be Octal Small Form-factor Pluggable (OSFP) modules. OSFP modules refer to high-speed transceiver modules designed for rapid data communication, particularly in environments requiring significant bandwidth, such as data centers and high-performance computing systems. These modules support extremely high data rates, typically up to 400 Gbps per module, with future capabilities extending to 800 Gbps or more. OSFP modules interface with the system via the PCIe interface, enabling fast and efficient data transfer between the integrated CPU-GPU components and external networks or other connected systems. Their hot-pluggable nature allows for easy insertion or removal without the need to power down the system, offering flexibility and ease of maintenance, which is crucial in critical-uptime environments. Additionally, OSFP modules are designed for high density, maximizing the number of high-speed connections within limited space, such as in densely packed server racks. By adhering to the latest networking standards, OSFP modules ensure the computing system 900 remains capable of meeting increasing data demands and can be upgraded to support future advancements in network speeds, thus contributing to the system's overall performance and scalability.

In at least one embodiment, the computing system 900 can be considered a data-network configuration with full-bandwidth intra-server NVLinks. In this example, all eight tensor core GPUs 908 can simultaneously saturate eighteen NVLinks to other GPUs within the server. The bandwidth is limited by over-subscription from multiple other GPUs. In another embodiments, data-network configuration can be a half-bandwidth intra-server NVLinks. In this example, all eight tensor core GPUs 908 can half-subscribe eighteen NVLinks to GPUs in other servers. Four tensor core GPUs 908 can saturate eighteen NVLinks to GPUs in other servers. This is equivalent of full-bandwidth on AllReduce with Scalable Hierarchical Aggregation and Reduction Protocol (SHARP). The reduction in all-2-all (All2All) bandwidth is a balance with server complexity and costs. In at least one embodiment, all eight tensor core GPUs 908 can independently transfer data, using Remote Direct Memory Access (RDMA) protocol, over its own dedicated switch (e.g., 400 Gb/s HCA/NIC) in an multi-rail InfiniBand/Ethernet configuration. In this example, 800 GBps of aggregate full-duplex to non-NVLink network devices.

The NICs/switches of computing system 900 can include the various embodiments described herein with respect to FIG. 1 to FIG. 4.

In at least one embodiment, the computing system 900 is used for high-speed network communication and includes a processing unit (e.g., CPU 902, CPU 904, switches 906, tensor core GPUs 908, switches 910, high-speed transceiver modules 912), and a network interface coupled to the processing unit. The network interface can include a receiver or a transceiver and perform the corresponding operations and functionalities described herein. The processing unit can include a CPU, a GPU, a DPU, a network adapter, a network switch, an NVLink switch, or the like.

In at least one embodiment, the computing system 900 includes a host device and an auxiliary device. The auxiliary device includes a device memory and a processor, communicably coupled to the device memory. The auxiliary device performs the operations described herein with respect to FIG. 1 to FIG. 4. The auxiliary device can include a GPU. The auxiliary device can include a DPU. The auxiliary device can include a DPU. The auxiliary device can include accelerator hardware.

Other variations are within the scope of the present disclosure. Thus, while disclosed techniques are susceptible to various modifications and alternative constructions, certain illustrated embodiments thereof are shown in drawings and have been described above in detail. It should be understood, however, that there is no intention to limit the disclosure to a specific form or forms disclosed, but on the contrary, the intention is to cover all modifications, alternative constructions, and equivalents falling within the spirit and scope of the disclosure, as defined in appended claims.

Use of terms “a” and “an” and “the” and similar referents in the context of describing disclosed embodiments (especially in the context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitations of ranges of values herein are merely intended to serve as a shorthand method of referring individually to each separate value falling within the range, unless otherwise indicated herein, and each separate value is incorporated into the specification as if it were individually recited herein. In at least one embodiment, the use of the term “set” (e.g., “a set of items”) or “subset” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but subset and corresponding set may be equal.

Conjunctive language, such as phrases of the form “at least one of A, B, and C,” or “at least one of A, B and C,” unless specifically stated otherwise or otherwise clearly contradicted by context, is otherwise understood with the context as used in general to present that an item, term, etc., may be either A or B or C, or any nonempty subset of the set of A and B and C. For instance, in an illustrative example of a set having three members, conjunctive phrases “at least one of A, B, and C” and “at least one of A, B and C” refer to any of the following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, the term “plurality” indicates a state of being plural (e.g., “a plurality of items” indicates multiple items). In at least one embodiment, the number of items in a plurality is at least two, but can be more when so indicated either explicitly or by context. Further, unless stated otherwise or otherwise clear from context, the phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in the form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause a computer system to perform operations described herein. In at least one embodiment, a set of non-transitory computer-readable storage media comprises multiple non-transitory computer-readable storage media and one or more of individual non-transitory storage media of multiple non-transitory computer-readable storage media lack all of the code while multiple non-transitory computer-readable storage media collectively store all of the code. In at least one embodiment, executable instructions are executed such that different instructions are executed by different processors.

Accordingly, in at least one embodiment, computer systems are configured to implement one or more services that singly or collectively perform operations of processes described herein, and such computer systems are configured with applicable hardware and/or software that enable the performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

All references, including publications, patent applications, and patents, cited herein are hereby incorporated by reference to the same extent as if each reference were individually and specifically indicated to be incorporated by reference and were set forth in its entirety herein.

In description and claims, the terms “coupled” and “connected,” along with their derivatives, may be used. It should be understood that these terms may not be intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to actions and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, the term “processor” may refer to any device or portion of a device that processes electronic data from registers and/or memory and transform that electronic data into other electronic data that may be stored in registers and/or memory. As non-limiting examples, a “processor” may be a network device or a MACsec device. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously, or intermittently. In at least one embodiment, the terms “system” and “method” are used herein interchangeably insofar as the system may embody one or more methods, and methods may be considered a system.

In the present document, references may be made to obtaining, acquiring, receiving, or inputting analog or digital data into a sub-system, computer system, or computer-implemented machine. In at least one embodiment, the process of obtaining, acquiring, receiving, or inputting analog and digital data can be accomplished in a variety of ways, such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface, or an inter-process communication mechanism.

Although descriptions herein set forth example embodiments of described techniques, other architectures may be used to implement described functionality, and are intended to be within the scope of this disclosure. Furthermore, although specific distributions of responsibilities may be defined above for purposes of description, various functions and responsibilities might be distributed and divided in different ways, depending on circumstances.

Furthermore, although the subject matter has been described in language specific to structural features and/or methodological acts, it is to be understood that the subject matter claimed in appended claims is not necessarily limited to specific features or acts described. Rather, specific features and acts are disclosed as exemplary forms of implementing the claims.

What is claimed is:

1. A circuit comprising:
clock detection circuitry to detect, at transitions of a clock signal transmitted across an alternating current (AC)-coupled unidirectional link, a first maximum value and a first minimum value of common mode-based amplitudes of the clock signal; and
a data receiver (RX) circuit coupled to the clock detection circuitry, wherein the data RX circuit is configured to:
receive a data signal from a data channel of the AC-coupled unidirectional link;
impose a second maximum value and a second minimum value on bit transitions of the data signal based on, respectively, the first maximum value and the first minimum value obtained from the clock signal; and
sample the data signal using the clock signal.

2. The circuit of claim 1, wherein the first maximum value and the first minimum value comprise direct-current (DC) analog levels of the clock signal and the second maximum value and the second minimum value comprise corresponding DC analog levels of the data signal.

3. The circuit of claim 1, wherein to impose the second maximum value and the second minimum value on the bit transitions of the data signal, the data RX circuit is to cause the second maximum value to match the first maximum value and the second minimum value to match the first minimum value.

4. The circuit of claim 1, wherein the data RX circuit comprises:
an input terminal coupled to the data channel;
one or more samplers to sample the data signal;
a series of inverters coupled between the input terminal and the one or more samplers; and direct-current (DC) restoration circuitry to cause the second maximum value and the second minimum value of bit transitions of the data signal to match the first maximum value and the first minimum value of the clock signal, respectively.

5. The circuit of claim 4, wherein the DC restoration circuitry further comprises:
a first switch coupled to a first terminal, wherein the first terminal is to receive the first maximum value from the clock detection circuitry;
a second switch coupled to a second terminal, wherein the second terminal is to receive the first minimum value from the clock detection circuitry; and
a resistor coupled between the first switch and the second switch and the input terminal;
wherein an output of an inverter of the series of inverters comprises a clock level control signal to activate one of the first switch or the second switch while deactivating the other of the first switch and the second switch.

6. The circuit of claim 1, further comprising a clock RX circuit comprising:
an input terminal to receive the clock signal transmitted across an alternating current (AC)-coupled unidirectional link; and
a series of inverters coupled between the input terminal and one or more samplers of the data RX circuit.

7. The circuit of claim 1, wherein the clock detection circuitry comprises:
an analog-to-digital converter (ADC) coupled to an input terminal of the clock signal, the ADC to:
sample the clock signal to determine, as digital values, a first maximum amplitude value and a first minimum amplitude value; and
store, in memory, the first maximum amplitude value and the first minimum amplitude value of the clock signal; and
a digital-to-analog converter (DAC) to:
retrieve, from the memory, the first maximum amplitude value and the first minimum amplitude value;
convert the first maximum amplitude value to the first maximum value for the data RX circuit; and
convert the first minimum amplitude value to the first minimum value for the data RX circuit.

8. The circuit of claim 1, wherein the clock signal comprises a differential clock signal, and the circuit further comprises a clock RX circuit comprising:
a first input terminal to receive a first signal of the differential clock signal; and
a second input terminal to receive a second signal of the differential clock signal;
wherein the clock detection circuitry comprises a peak-to-peak detector coupled between the first input terminal and the second input terminal, the peak-to-peak detector to detect the first maximum value from the first signal and detect the first minimum value from the second signal of the differential clock signal.

9. The circuit of claim 8, wherein the clock detection circuitry further comprises:
a first analog voltage buffer, coupled to the peak-to-peak detector, to hold and drive the first maximum value to the data RX circuit; and
a second analog voltage buffer, coupled to the peak-to-peak detector, to hold and drive the first minimum value to the data RX circuit.

10. A system comprising:
a data channel of a short-reach alternating current (AC)-coupled unidirectional link, the data channel to carry a data signal from a processing core;
a clock channel of the short-reach AC-coupled unidirectional link, the clock channel to carry a clock signal from the processing core;
clock detection circuitry coupled to the clock channel, the clock detection circuitry to detect, at transitions of the clock signal, a first maximum value and a first minimum value of common mode-based amplitudes of the clock signal; and
a data receiver (RX) circuit coupled to the clock detection circuitry and the data channel, wherein the data RX circuit is configured to:
receive the data signal from the data channel;
impose a second maximum value and a second minimum value on bit transitions of the data signal based on, respectively, the first maximum value and the first minimum value obtained from the clock signal; and
sample the data signal using the clock signal.

11. The system of claim 10, wherein the first maximum value and the first minimum value comprise direct-current (DC) analog levels of the clock signal and the second maximum value and the second minimum value comprise corresponding DC analog levels of the data signal.

12. The system of claim 10, wherein to impose the second maximum value and the second minimum value on the bit transitions of the data signal, the data RX circuit is to cause the second maximum value to match the first maximum value and the second minimum value to match the first minimum value.

13. The system of claim 10, wherein the data RX circuit comprises:
an input terminal coupled to the data channel;
one or more samplers to sample the data signal;
a series of inverters coupled between the input terminal and the one or more samplers; and
direct-current (DC) restoration circuitry to cause the second maximum value and the second minimum value of bit transitions of the data signal to match the first maximum value and the first minimum value of the clock signal, respectively.

14. The system of claim 13, wherein the DC restoration circuitry further comprises:
a first switch coupled to a first terminal, wherein the first terminal is to receive the first maximum value from the clock detection circuitry;
a second switch coupled to a second terminal, wherein the second terminal is to receive the first minimum value from the clock detection circuitry; and
a resistor coupled between the first switch and the second switch and the input terminal;
wherein an output of an inverter of the series of inverters comprises a clock level control signal to activate one of the first switch or the second switch while deactivating the other of the first switch and the second switch.

15. The system of claim 10, further comprising a clock RX circuit comprising:
an input terminal to receive the clock signal transmitted across an alternating current (AC)-coupled unidirectional link; and
a series of inverters coupled between the input terminal and one or more samplers of the data RX circuit.

16. The system of claim 10, wherein the clock detection circuitry comprises:
an analog-to-digital converter (ADC) coupled to an input terminal of the clock signal, the ADC to:
sample the clock signal to determine, as digital values, a first maximum amplitude value and a first minimum amplitude value; and
store, in memory, the first maximum amplitude value and the first minimum amplitude value of the clock signal; and
a digital-to-analog converter (DAC) to:
retrieve, from the memory, the first maximum amplitude value and the first minimum amplitude value;
convert the first maximum amplitude value to the first maximum value for the data RX circuit; and
convert the first minimum amplitude value to the first minimum value for the data RX circuit.

17. The system of claim 10, wherein the clock signal comprises a differential clock signal, and the circuit further comprises a clock RX circuit comprising:
a first input terminal to receive a first signal of the differential clock signal; and
a second input terminal to receive a second signal of the differential clock signal;
wherein the clock detection circuitry comprises a peak-to-peak detector coupled between the first input terminal and the second input terminal, the peak-to-peak detector to detect the first maximum value from the first signal and detect the first minimum value from the second signal of the differential clock signal.

18. The system of claim 17, wherein the clock detection circuitry further comprises:
a first analog voltage buffer, coupled to the peak-to-peak detector, to hold and drive the first maximum value to the data RX circuit; and
a second analog voltage buffer, coupled to the peak-to-peak detector, to hold and drive the first minimum value to the data RX circuit.

19. A method of operating a circuit comprising clock detection circuitry and a data receiver (RX) circuit coupled to the clock detection circuit, wherein the method of operating the circuit comprises:
detecting, by the clock detection circuitry, at transitions of a clock signal transmitted across an alternating current (AC)-coupled unidirectional link, a first maximum value and a first minimum value of common mode-based amplitudes of the clock signal;
receiving, by the data RX circuit, a data signal from a data channel of the AC-coupled unidirectional link;
imposing a second maximum value and a second minimum value on bit transitions of the data signal based on, respectively, the first maximum value and the first minimum value obtained from the clock signal; and
sampling, by the data RX circuit, the data signal using the clock signal.

20. The method of claim 19, wherein imposing the second maximum value and the second minimum value on the bit transitions of the data signal comprises causing the second maximum value to match the first maximum value and the second minimum value to match the first minimum value.

21. A communication system for high-speed network communication, the communication system comprising:
a processing unit; and
a network interface coupled to the processing unit, wherein the network interface comprises a receiver device comprising:
clock detection circuitry to detect, at transitions of a clock signal transmitted across an alternating current (AC)-coupled unidirectional link, a first maximum value and a first minimum value of common mode-based amplitudes of the clock signal; and
a data receiver (RX) circuit coupled to the clock detection circuitry, wherein the data RX circuit is configured to:
receive a data signal from a data channel of the AC-coupled unidirectional link;
impose a second maximum value and a second minimum value on bit transitions of the data signal based on, respectively, the first maximum value and the first minimum value obtained from the clock signal; and
sample the data signal using the clock signal.

22. The communication system of claim 21, wherein the first maximum value and the first minimum value comprise direct-current (DC) analog levels of the clock signal and the second maximum value and the second minimum value comprise corresponding DC analog levels of the data signal.

23. The communication system of claim 21, wherein to impose the second maximum value and the second minimum value on the bit transitions of the data signal, the data RX circuit is to cause the second maximum value to match the first maximum value and the second minimum value to match the first minimum value.
